(19) United States
(12) Patent Application Publication
(10) Pub. No.: US 2025/0069912 A1
(43) Pub. Date: Feb. 27, 2025

(54) HEATING DEVICE AND SUBSTRATE PROCESSING APPARATUS

(71) Applicant: Tokyo Electron Limited, Tokyo (JP)

(72) Inventor: Einosuke TSUDA, Nirasaki City (JP)

(21) Appl. No.: 18/941,290

(22) Filed: Nov. 8, 2024

Related U.S. Application Data
(63) Continuation of application No. PCT/JP2023/016465, filed on Apr. 26, 2023.

(30) Foreign Application Priority Data
May 10, 2022 (JP) 2022-077487

(51) Int. Cl. H01L 21/67; H01L 21/683; H05B 3/28

(52) U.S. Cl. CPC H01L 21/67103; H05B 3/28; H01L 21/6831

(57) ABSTRACT

A heating device for heating a substrate directly on the heating device or indirectly placed on the heating device via another member, includes a linear heater and a base having a groove depressed from a side opposite the substrate toward the substrate, the linear heater being fixed inside the groove. The groove has a contact portion provided on a front side of the groove so as to come into contact with the linear heater and a non-contact portion provided on a back side of the groove so as not to come into contact with the linear heater.

### CROSS-REFERENCE TO RELATED APPLICATIONS

This application is a bypass continuation application of International Application No. PCT/JP2023/016465 having an international filing date of Apr. 26, 2023 and designating the United States, the international application being based upon and claiming the benefit of priority from Japanese Patent Application No. 2022-077487, filed on May 10, 2022, the entire contents of which are incorporated herein by reference.

### TECHNICAL FIELD

The present disclosure relates to a heating device and a substrate processing apparatus.

### BACKGROUND

In Patent Document 1, a stage structure is provided at a bottom portion inside a processing container of a processing apparatus. The stage structure includes a stage for placing and supporting a semiconductor wafer thereon. The stage includes a stage main body having a thick thickness and made of transparent quartz, and a heat diffusion plate provided on an upper surface of the stage main body and made of an opaque dielectric different from the stage main body. A heater is provided to be embedded in the stage main body. The heater has a heater wire made of a carbon wire and is provided to have a predetermined pattern shape over approximately the entire surface of the stage main body.

### PRIOR ART DOCUMENT

### Patent Document

Patent Document 1: Japanese Laid-Open Patent Publication No. 2011-054838

### SUMMARY

According to one embodiment of the present disclosure, a heating device configured to heat a substrate directly on the heating device or indirectly placed on the heating device via another member, includes a linear heater, and a base having a groove depressed from a side opposite the substrate toward the substrate. The linear heater is fixed inside the groove. The groove has a contact portion provided on a front side of the groove so as to come into contact with the linear heater and a non-contact portion provided on a back side of the groove so as not to come into contact with the linear heater.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory diagram schematically illustrating a configuration of a film forming apparatus as a substrate processing apparatus according to the present embodiment.

FIG. 2 is a partially enlarged cross-sectional view of a stage of FIG. 1.

FIG. 3 is a partially enlarged cross-sectional view of a base.

FIG. 4 is a diagram illustrating dimensions of the base.

FIG. 5 is a partially enlarged cross-sectional view illustrating Modification 1 of the stage.

FIG. 6 is a partially enlarged cross-sectional view illustrating Modification 2 of the stage.

FIG. 7 is a partially enlarged cross-sectional view illustrating Modification 1 of grooves.

FIG. 8 is a partially enlarged cross-sectional view illustrating Modification 2 of the grooves.

FIG. 9 is a cross-sectional view illustrating Modification 3 of the stage.

FIG. 10 is a diagram illustrating results of a simulation performed for a temperature of a placement surface for a wafer when the placement surface is heated by a heater inside the stage.

FIG. 11 is a diagram illustrating results of the simulation performed for the temperature of the placement surface for the water when the placement surface is heated by the heater inside the stage.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of semiconductor devices and the like, various substrate processes including a film formation process of forming a predetermined film on a substrate such as a semiconductor wafer (hereinafter referred to as “wafer”) are performed. Such substrate processes are performed in a state in which the substrate is placed on a placement surface of a stage inside a processing container in a depressurized state.

Further, the substrate process may be performed in a state in which the substrate has been heated. In this case, the substrate is heated by a heating device. The heating device includes a base formed in a plate shape, and a heater formed in a linear shape and arranged inside the base. The heating device heats the base with the heater to heat the substrate placed on an upper surface (the placement surface) of the base, or to heat the substrate via another member placed on the base and having a placement surface.

However, when the substrate is heated by the heating device, a portion of the substrate directly above the heater may be heated to a higher temperature than those of surrounding portions. In other words, there are cases where a temperature distribution of the same shape as an arrangement pattern of the heater occurs on the substrate. As a result, the arrangement pattern of the heater may be transferred to processing results of the substrate. An in-plane heating uniformity of the substrate by the heating device may be improved by increasing a thickness of the base including the heater arranged therein. However, the increase in thickness as described above is not desirable in terms of factors such as a heating responsiveness of the substrate by the heater, etc.

Therefore, a technique according to the present disclosure improves in-plane heating uniformity of a substrate using the heating device which heats the substrate placed thereon, without increasing the thickness of the heating device.

Hereinafter, a heating device and a substrate processing apparatus according to the present embodiment will be described with reference to the drawings. Further, in the subject specification and the drawings, components having substantially identical functions and configurations will be designated by like reference numerals and redundant descriptions thereof will be omitted.

### Film Forming Apparatus

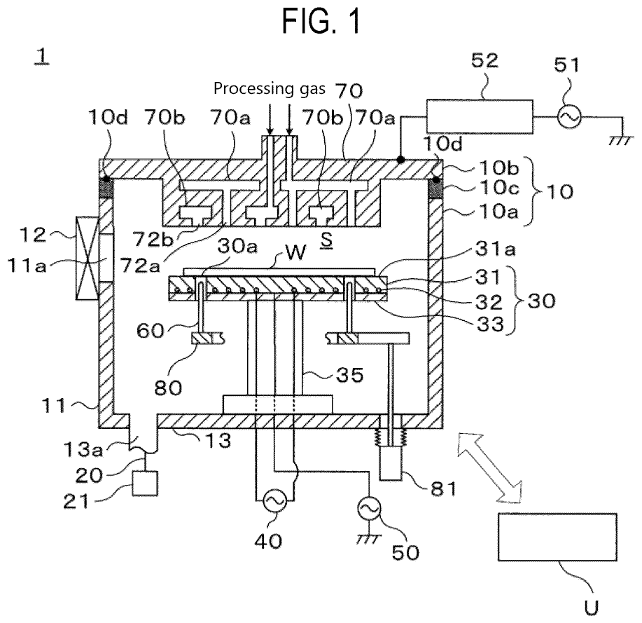

FIG. 1 is an explanatory diagram schematically illustrating a configuration of a film forming apparatus as the substrate processing apparatus according to the present embodiment, and illustrates a portion of the film forming apparatus in a cross-sectional view.

A film forming apparatus 1 of FIG. 1 is configured to process a wafer W as a substrate (specifically, to perform film formation) and form a predetermined film on the wafer W.

The film forming apparatus 1 includes a processing container 10 and a stage 30 serving as a heating device. The processing container 10 includes the stage 30 provided therein, and is configured to be depressurized. The processing container 10 includes a container main body 10a formed in, for example, a cylindrical shape with a bottom.

The container main body 10a is made of, for example, a metallic material. A loading/unloading port 11a for the wafer W is provided in a sidewall 11 of the container main body 10a. A gate valve 12 is provided at the loading/unloading port 11a to open or close the loading/unloading port 11a.

An exhaust port 13a is formed in a bottom wall 13 of the container main body 10a. Further, one end of an exhaust pipe 20 is connected to the exhaust port 13a. The other end of the exhaust pipe 20 is connected to an exhaust mechanism 21 including a vacuum pump and the like.

The stage 30 includes a base 31, a heater 32, and a cover member 33. The base 31 is formed in a plate shape (specifically, a circular disc shape). In this example, an upper surface of the base 31 constitutes a placement surface 31a on which the wafer W is placed. The base 31 is formed of a metallic material (e.g., aluminum) with high thermal conductivity.

The heater 32 is a sheath heater formed in a linear shape. One or plural heaters 32 are arranged inside the base 31 (specifically, inside a groove 31b to be described later) along a plate surface of the base 31. In a case in which one heater 32 is provided, it may be arranged in a spiral shape in a plan view. In a case in which the plurality of heaters 32 are provided, they may be respectively arranged in a concentric annular shape. As a result, the plurality of heaters 32 may be arranged at equal intervals in the base 31 in a vertical cross-sectional view. The heater(s) 32 is connected to a heater power supply 40. The heater power supply 40 is controlled by a controller U to be described later.

The cover member 33 is formed in a plate shape (specifically, a circular disc shape), and blocks an opening (to be described later) of the groove 31b in the base 31. The cover member 33 is formed of, for example, a metallic material (e.g., aluminum).

Further, the stage 30 is connected to a radio-frequency power supply 50 for supplying radio-frequency power for bias. Specifically, the radio-frequency power supply 50 is connected to, for example, the cover member 33 of the stage 30.

Further, the stage 30 has a plurality of through-holes 30a formed to penetrate vertically. A lift pin 60 (to be described later) is inserted into each of the through-holes 30a. A more detailed structure of the stage 30 will be described later.

The stage 30 is supported by, for example, a support member 35 provided to stand on a bottom center of the processing container 10. Further, the stage 30 accommodates the lift pins 60 inserted into the aforementioned through-holes 30a. The lift pins 60 are used to deliver the wafer W between a wafer transfer device (not illustrated), which is inserted from outside of the processing container 10 into the processing container 10, and the stage 30. The lift pins 60 are configured to be movable upward and downward with respect to the placement surface 31a of the stage 30 via the respective through-holes 30a.

Further, the processing container 10 includes a ceiling wall member 10b which blocks an upper opening of the container main body 10a. The ceiling wall member 10b is connected to an upper end of the container main body 10a via an insulating member 10c having electrical insulation properties.

The ceiling wall member 10b is formed of, for example, a metallic material, and includes a shower head 70 configured to inject a processing gas into a processing space S. For example, gas diffusion chambers 71a and 71b are provided inside the shower head 70. The processing gas introduced into the gas diffusion chambers 70a and 70b diffuses horizontally inside the gas diffusion chambers 70a and 70b and subsequently, are injected into the processing space S via injection holes 72a and 72b, which are respectively in communication with the gas diffusion chambers 70a and 70b. A plurality of injection holes 72a and a plurality of injection holes 72b may be provided. Each of the gas diffusion chambers 70a and 70b is connected to one end of a supply pipe (not illustrated). The other end of the supply pipe is connected to a supply mechanism (not illustrated) that includes a source of a film-forming gas, and the like.

A sealing member 10d such as an O-ring is provided to secure airtightness between the ceiling wall member 10b and the insulating member 10c. Further, a radio-frequency power supply 51 configured to supply radio-frequency power for plasma generation is connected to the ceiling wall member 10b via a matching circuit 52.

Further, the film forming apparatus 1 is provided with a support member 80 and a moving mechanism 81, which are used for the lift pins 60. The support member 80 supports the lift pins 60. The support member 80 is formed in, for example, a circular ring shape in a plan view. The moving mechanism 81 raises or lowers the support member 80 to raise or lower the lift pins 60. The moving mechanism 81 includes a drive source (not illustrated) such as a motor to generate a drive force for raising or lowering the support member 80.

The film forming apparatus 1 configured as above is provided with the controller U. The controller U is constituted with a computer including, for example, a processor such as a CPU, and a memory, and includes a program storage (not illustrated). The program storage stores a program for implementing the processing of the wafer W by the film forming apparatus 1. Further, the program may be recorded on a computer-readable storage medium and may be installed from the storage medium in the controller U. Further, the storage medium may be transitory or non-transitory.

### Stage 30

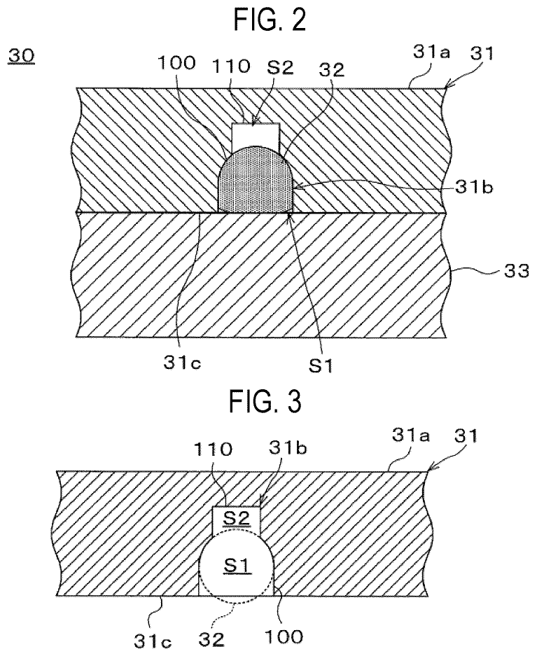

Next, a structure of the stage 30 will be described in detail. FIG. 2 is a partially enlarged cross-sectional view of the stage 30. FIG. 3 is a partially enlarged cross-sectional view of the base 31. FIG. 4 is a diagram illustrating dimensions of the base 31.

As described above, the stage 30 includes the base 31, the heater 32, and the cover member 33. As illustrated in FIGS. 2 and 3, the base 31 has the groove 31b in which the heater 32 is fixed.

The groove 31b is formed in the base 31 to be depressed from a side opposite the wafer W toward the wafer W, that is, to be depressed upward from a lower surface 31c of the base 31, which is opposite the placement surface 31a of the base 31. In addition, although not illustrated, a shape of the groove 31b in a plan view corresponds to the arrangement pattern of the heater 32, and may be, for example, a spiral shape or annular shape (specifically, a circular ring shape) centered on a center of the base 31. The groove 31b has a contact portion 100 which comes into contact with the heater 32 on a front side, i.e., a lower side of the groove 31b, and a non-contact portion 110 which does not come into contact with the heater 32 on a back side, that is, an upper side of the groove 31b.

The contact portion 100 is formed such that, for example, most of the contact portion 100 comes into contact with the heater 32. The contact portion 100 forms a space S1 which is open on both the front side and the back side, that is, both the lower side and the upper side, and accommodates at least half of the heater 32. The heater 32 is vertically positioned inside the base 31 by a back-side end portion (i.e., an upper end portion) of the contact portion 100.

The non-contact portion 110 is formed such that the entirety thereof does not come into contact with the heater 32 at all. The non-contact portion 110 forms a space S2 which is open on the front side, that is, the lower side. Specifically, the space S2 is open toward the space S1.

In other words, the non-contact portion 110 is formed to be further depressed from the back-side end portion (i.e., the upper end portion) of the contact portion 100, which is depressed from the lower surface of the base 31.

Further, the space S2 formed by the non-contact portion 110 has, for example, a rectangular shape in a cross-sectional view along a direction in which the groove 31b extends (that is, in a vertical cross-sectional view). In addition, the space S1 formed by the contact portion 100 has, for example, a shape in which a semicircular upper portion thereof is connected to a lower rectangular end portion of the space S2 in a vertical cross-sectional view.

As illustrated in FIG. 2, the cover member 33 is fixed to the base 31 in a state in which the cover member 33 blocks a bottom opening of the groove 31b and the heater 32 is forcibly pressed between the contact portion 100 and the cover member 33. The fixation of the cover member 33 to the base 31 is implemented by, for example, brazing. As illustrated in FIG. 3, the heater 32 has, for example, a circular cross-sectional shape, in a state in which an external pressure, such as being forcibly pressed by the cover member 33, is not applied. Hereinafter, the expression “diameter of the heater 32 in a vertical cross-sectional view” refers to a diameter of the heater 32 in a vertical cross-sectional view in the state in which an external pressure is not applied as described above.

Next, examples of dimensions of the base 31 and the heater 32 in a vertical cross-sectional view will be described.

A diameter R of the heater 32 in a vertical cross-sectional view (see FIG. 4) is, for example, 5 mm to 10 mm. Further, a distance L1 between adjacent heaters 32 in a vertical cross-sectional view is, for example, 1.5 times or more the diameter R of the heater 32.

A width H1 of the space S1 formed by the contact portion 100 of the groove 31b in the base 31 in a vertical cross-sectional view is approximately equal to the diameter R of the heater 32. Further, a depth D1 of the contact portion 100 in a vertical cross-sectional view is set such that a portion of the heater 32 protrudes from the lower surface 31c of the base 31 in a state in which the heater 32 is accommodated in the groove 31b and the opening of the groove 31b is not blocked by the cover member 33.

On the other hand, a width H2 of an opening on the front side (i.e., the lower side) of the space S2 formed by the non-contact portion 110 is, for example, 15% or more, more particularly 75% or more, of the diameter (that is, thickness) R of the heater 32. However, from the viewpoint of vertically positioning the heater 32 inside the base 31, the width H2 may preferably be 90% or less of the diameter of the heater 32.

Further, a depth D2 of the non-contact portion 110 in a vertical cross-sectional view is, for example, 20% to 100% of the diameter R of the heater 32. Further, a distance L2 from an upper end of the non-contact portion 110 to a surface facing the wafer W, that is, the placement surface 31a, is, for example, 15% to 60% of the diameter R of the heater 32, more specifically, 1 mm and 4 mm. By setting the distance L2 to 4 mm or less, it is possible to reduce the thickness of the stage 30.

### Processing of Wafer W

Next, an example in which the processing of the wafer W is performed using the film forming apparatus 1 will be described. In addition, the processing of the wafer W is performed under the control of the controller U.

### Step S1: Placement

First, the wafer W is placed on the placement surface 31a of the stage 30. Specifically, for example, the gate valve 12, which is provided at the loading/unloading port 11a for the wafer W in the processing container 10, is open. A transfer mechanism (not illustrated) configured to hold the wafer W is inserted into the processing container 10 kept in a vacuum atmosphere from a transfer chamber (not illustrated), which is adjacent to the processing container 10 and is kept in a vacuum atmosphere, via the loading/unloading port 11a. Then, the wafer W is transferred above the stage 30. Subsequently, the wafer W is delivered on the lift pins 60 in a raised state. Thereafter, the transfer mechanism is withdrawn from the processing container 10, and the gate valve 12 is closed. At the same time, the lift pins 60 are lowered, and the wafer W is placed on the placement surface 31a of the stage 30, which has been heated to a predetermined temperature by the heater 32.

As described above, the heater 32 is provided inside the groove 31b, and the non-contact portion 110 exists between the surface (i.e., the placement surface 31a) of the base 31 which faces the wafer W and the heater 32. In other words, an upper portion of the heater 32 close to the placement surface 31a does not come into contact with the base 31. Therefore, heat from the upper portion of the heater 32 is hardly radiated to the placement surface 31a.

Further, a portion of the heater 32 other than the upper portion comes into contact with the base 31. Since the portion other than the upper portion of the heater 32 is positioned far from the placement surface 31a, heat from the respective portion is more likely to diffuse horizontally before being radiated to the placement surface 31a.

Accordingly, compared to a comparative configuration in which the upper portion of the heater 32 and the base 31 are in contact with each other without the non-contact portion 110, the placement surface 31a may be heated by the heater 32 with in-plane uniformity, which makes it possible to heat the wafer W placed on the placement surface 31a with in-plane uniformity.

### Step S2: Film Formation

Thereafter, a predetermined film is formed on the wafer W. Specifically, for example, the supply of the processing gas including the film-forming gas from the shower head 70, the supply of the radio-frequency power for bias from the radio-frequency power supply 50, and the supply of the radio-frequency power for plasma generation from the radio-frequency power supply 51 are performed. Thus, the wafer W is processed by a plasma of the processing gas so that the predetermined film is formed on the wafer W.

After the formation of the predetermined film is completed, the supply of the processing gas from the shower head 70, the supply of the radio-frequency power for bias from the radio-frequency power supply 50, and the supply of the radio-frequency power for plasma generation from the radio-frequency power supply 51 are stopped.

### Step S3: Unloading

Thereafter, the wafer W is unloaded from the processing container 10 in a reverse order of the operation of step S1.

### Major Effects of Present Embodiment

As described above, according to the present embodiment, it is possible to improve the in-plane heating uniformity of the wafer W placed on the stage 30 due to heating by the stage 30. In other words, it is possible to suppress the arrangement pattern of the heater 32 from being transferred to the temperature distribution of the wafer W heated by the stage 30, or to the film formation results of the wafer W.

Further, according to the present embodiment, it is possible to improve the in-plane heating uniformity described above without increasing the thickness of the stage 30. Therefore, it is possible to suppress effects caused by an increase in the thickness of the stage 30, as follows:
Degradation in heating responsiveness of the wafer W by the heater 32;
Deterioration in handling of the stage 30;
Increase in cost of the stage 30; and
Increase in consumption amount of energy.

Further, by suppressing the increase in the thickness of the stage 30, it is possible to efficiently utilize an internal space of the processing container 10 in which the stage 30 is installed.

### Modification 1 of Stage

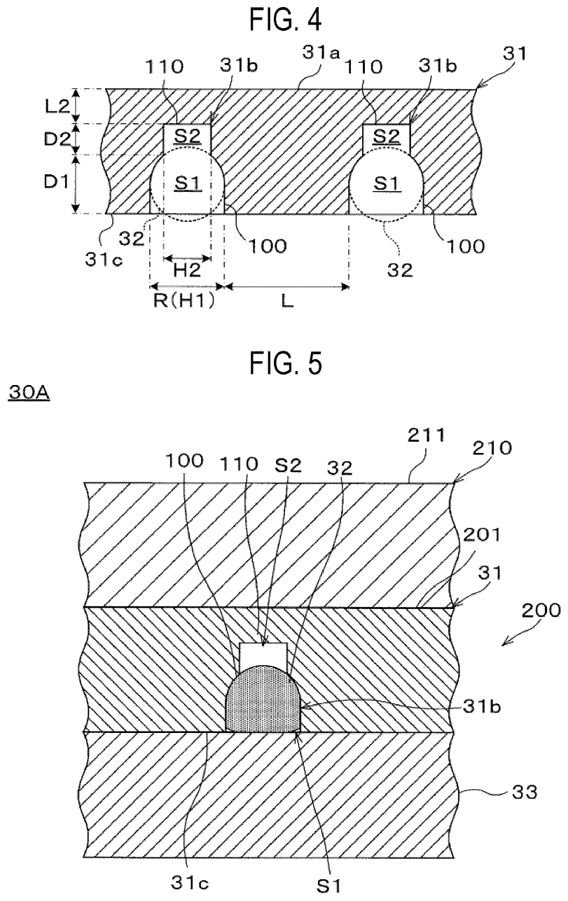

FIG. 5 is a partially enlarged cross-sectional view illustrating Modification 1 of the stage.

In the above example, the stage 30 itself serves as the heating device according to the present disclosure, the upper surface of the base 31 of the stage 30 functions as the placement surface 31a for the wafer W, and the wafer W is placed directly on the stage 30, that is, the heating device.

In contrast, a stage 30A of FIG. 5 is provided with a heating device 200 which includes the base 31, the heater 32, and the cover member 33, and an additional member such as an electrostatic chuck 210 having a placement surface 211 on which the wafer W is placed. The electrostatic chuck 210 is fixed to a surface of the heating device 200 facing the wafer W, that is, an upper surface 201 of the base 31. In other words, the wafer W is indirectly placed on the heating device 200 via the electrostatic chuck 210. The heating device 200 heats the wafer W indirectly placed thereon.

The electrostatic chuck 210 is a member which electrostatically adsorbs and holds the wafer W placed on the placement surface 211. Specifically, the electrostatic chuck 210 is a member in which an electrode for electrostatic adsorption is embedded in a plate-shaped member made of a dielectric material, that is, a plate-shaped member having a relatively low thermal conductivity. Therefore, the temperature distribution on the placement surface 211 of the electrostatic chuck 210 may exhibit the same shape as the arrangement pattern of the heater 32. This may make the in-plane temperature of the wafer W placed on the placement surface 211 non-uniform. In contrast, in this example, the heating device 200 has the configuration in which the above-described groove 31b is provided in the base 31. This makes it possible to improve the in-plane heating uniformity of the wafer W indirectly placed on the heating device 200 due to heating by the heating device 200.

### Modification 2 of Stage

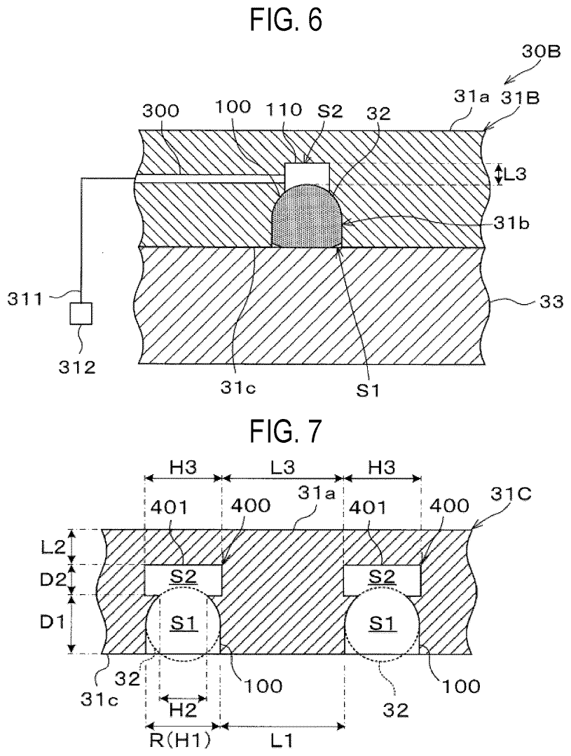

FIG. 6 is a partially enlarged cross-sectional view illustrating Modification 2 of the stage.

A stage 30B of FIG. 6 is configured such that an exhaust path 300 is formed in a base 31B. One end of the exhaust path 300 communicates with the space S2 formed by the non-contact portion 110 of the groove 31b, and the other end of the exhaust path 300 is connected to an exhaust mechanism 311 including a vacuum pump and the like via an exhaust pipe 310. With this configuration, the interior of the space S2 may be exhausted. Therefore, the upper portion of the heater 32 and the non-contact portion 110 of the groove 31b may be vacuum-insulated from each other. This may further suppress just above the upper portion of the heater 32 in the base 31B from being locally heated. Therefore, according to this example, it is possible to further improve the in-plane heating uniformity of the wafer W placed on the stage 30B due to heating by the stage 30B.

In addition, in a case in which the space S2 is exhausted, the present disclosers have confirmed from simulation results that when a distance L3 from the innermost portion of the groove 31b to the heater 32 is 1 mm or more, the heat radiation from the upper portion of the heater 32 to the base 31B may be suppressed.

### Modifications of Groove

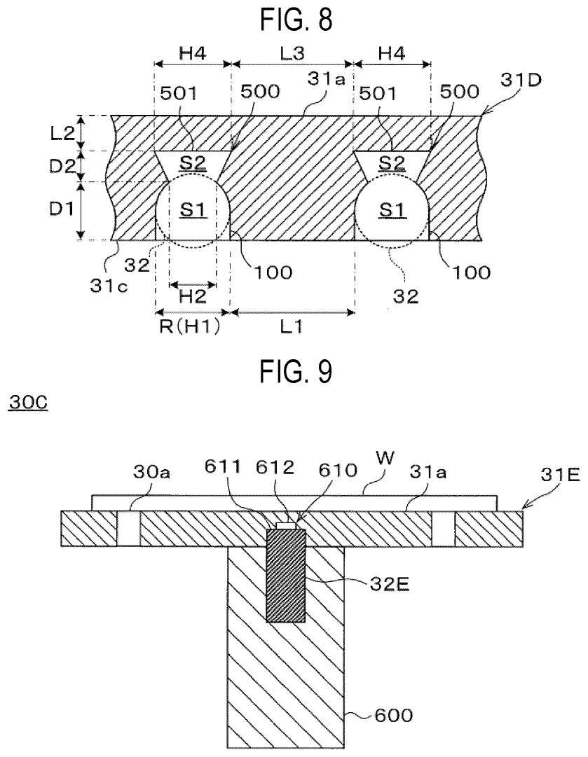

FIGS. 7 and 8 are partially enlarged cross-sectional views respectively illustrating Modifications 1 and 2 of the groove in which the heater 32 is fixed.

In the above example, the space S2 formed by the non-contact portion 110 of the groove 31b has the same horizontal width in a vertical cross-sectional view at the bottom opening portion and the upper portion above the bottom opening portion.

In contrast, as illustrated in FIG. 7, the space S2 formed by a non-contact portion 401 of a groove 400 in a base 31C may have a relatively wide horizontal width in a vertical cross-sectional view at the upper portion rather than the bottom opening portion. With this configuration, the heat from the heater 32 may further diffuse horizontally before being transferred to the placement surface 31a, which makes it possible to further improve the in-plane heating uniformity. In this case, a width H3 of the upper portion of the space S2 in a vertical cross-sectional view may be set such that a distance L3 between adjacent spaces S2 is greater than the diameter of the heater 32 and is also set to be less than or equal to 120% of the diameter R of the heater 32. This makes it possible to suppress the formation pattern of the space S2 in a plan view from being transferred to the temperature distribution or the like of the wafer W heated by the stage with the groove 400.

Further, as illustrated in FIG. 8, the space S2 formed by a non-contact portion 501 of a groove 500 in a base 31D may be formed such that a horizontal width thereof in a vertical cross-sectional view gradually widens toward the back side, that is, the upper side. Even in this example, the heat from the heater 32 may further diffuse horizontally before being transferred to the placement surface 31a, which makes it possible to further improve the in-plane heating uniformity.

In this case, a width H4 of the upper portion of the space S2 in a vertical cross-sectional view may be set such that the distance L3 between adjacent spaces S2 is greater than the diameter R of the heater 32 and is also set to be less than or equal to 120% of the diameter R of the heater 32. This makes it possible to suppress the formation pattern of the space S2 in a plan view from being transferred to the temperature distribution or the like of the wafer W heated by the stage with the groove 500.

### Modification 3 of Stage

FIG. 9 is a cross-sectional view illustrating Modification 3 of the stage.

In the above example, the heater 32 has been described as being a sheath heater. In this example, a heater 32E may be a cartridge heater formed in a linear shape. A stage 30C of this example includes a single heater 32E as the cartridge heater, a support member 600, and a base 31E.

The support member 600 is provided to stand on the bottom center of the processing container 10 to support the base 31E. A lower portion of the heater 32E is fixed inside the support member 600, and an upper portion thereof is fixed inside the base 31E.

The base 31E has a groove 610 in which the upper portion of the heater 32E is fixed. The groove 610 is provided on a lower side with a contact portion 611 which comes into contact with the heater 32E and on an upper side with a non-contact portion 612 which does not come into contact with the upper portion of the heater 32E.

By providing the heater 32E as in this example, only a central portion of the placement surface 31a may be locally heated at a high temperature. However, in this example, the non-contact portion 612 is provided at an upper side of the groove 610 in which the heater 32E is fixed. Therefore, heat from the center of an upper surface of the heater 32E is hardly radiated to the placement surface 31a. Thus, according to this example, it is possible to suppress the central portion of the placement surface 31a from being locally heated at a high temperature.

### TEST EXAMPLES

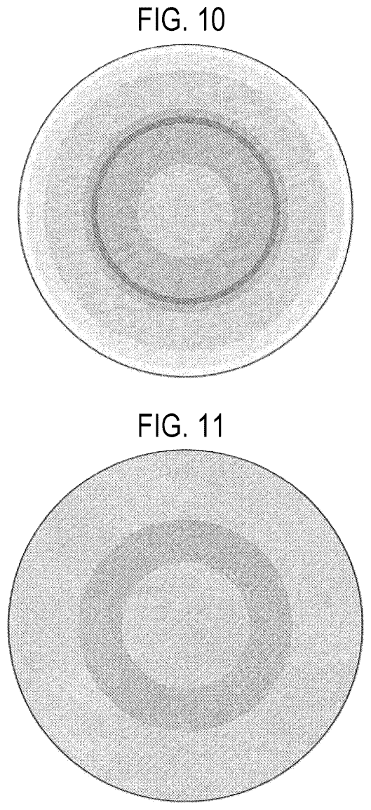

The present disclosers conducted simulations on the temperature of the placement surface when the placement surface for the wafer is heated by the heater provided inside the stage. FIGS. 10 and 11 are diagrams illustrating the simulation results, respectively. FIG. 10 illustrates the results of Test Example 1 and FIG. 11 illustrates the results of Test Example 2. Further, in FIGS. 10 and 11, the temperature of the placement surface is indicated by shading. Darker areas represent higher temperatures and lighter areas represent lower temperatures.

Test Examples 1 and 2 differ in the structure of the groove of the stage from each other. The stage in Test Example 2 has the groove 31b illustrated in FIG. 4, whereas the stage in Test Example 1 has a groove without the non-contact portion 110. In Test Example 1, the entire groove is in contact with the heater, and the upper portion of the heater is also in contact with the groove. In addition, hereinafter, for the sake of convenience in description, the stage in Test Example 1 will be described by the same reference numerals as those in Test Example 2.

Major simulation conditions other than the structure of the groove 31b are as follows:
Material of the base 31 of the stage 30: aluminum
Type of the heater 32: sheath heater
Distance from the placement surface 31a of the stage 30 to the upper end of the heater 32: 3.5 mm
Cross-sectional shape of the heater 32: circular shape
Diameter of the heater 32: 6.5 mm
Placement pattern of the heater 32: one circular ring centered on the center of the placement surface 31a
Width H2 of the space S2 in Test Example 2: 5 mm
Distance L2 from the upper end of the non-contact portion 110 to the placement surface 31a in Test Example 2: 1.5 mm
Distance L3 from the innermost portion of the groove 31b to the upper end of the heater 32 in Test Example 2: 2 mm

As illustrated in FIG. 10, in Test Example 1 in which the groove 31b including the heater 32 fixed therein does not have the non-contact portion 110, a high temperature region occurred on the placement surface 31a in a circular ring shape in a concentric relationship with the placement surface 31a. In contrast, in Test Example 2, as illustrated in FIG. 11, the temperature of the entire placement surface 31a was more uniform compared to that in Test Example 1. From these results, it can be seen that the in-plane heating uniformity of the wafer W by the stage 30 may be improved by forming the non-contact portion 110 in the groove 31b with the heater 32 fixed inside.

### Reference Embodiment

In the above embodiments, the technique of the present disclosure has been described to be applied to the heating device configured to heat a substrate, which is directly placed on the heating device or indirectly placed on the heating device via an additional member. The technique of the present disclosure may be applied to a heating device configured to heat a heating target which comes into direct contact with the heating device or comes into indirect contact with the heating device via an additional member.

According to the present disclosure, it is possible to improve in-plane heating uniformity of a substrate by a heating device configured to heat a substrate placed thereon, without increasing a thickness of the heating device.

The embodiments disclosed herein should be considered illustrative in all respects and not restrictive. The above embodiments may be omitted, replaced or modified in various embodiments without departing from the scope of the appended claims and their gist.

What is claimed is:

1. A heating device configured to heat a substrate directly on the heating device or indirectly placed on the heating device via another member, the heating device comprising:
a linear heater; and
a base having a groove depressed from a side opposite the substrate toward the substrate, the linear heater being fixed inside the groove,
wherein the groove has a contact portion provided on a front side of the groove so as to come into contact with the linear heater and a non-contact portion provided on a back side of the groove so as not to come into contact with the linear heater.

2. The heating device of claim 1, wherein the non-contact portion forms a space in which the front side is open.

3. The heating device of claim 2, wherein a width of an opening on the front side of the space in a cross-sectional view along a direction in which the groove extends is equal to or greater than 75% of a thickness of the linear heater.

4. The heating device of claim 2, wherein the space is rectangular in a cross-sectional view along a direction in which the groove extends.

5. The heating device of claim 2, wherein the space is formed to increase in width toward the back side in a cross-sectional view along a direction in which the groove extends.

6. The heating device of claim 2, wherein the base includes an exhaust path communicating with the space.

7. A substrate processing apparatus comprising:
the heating device of claim 1; and
a processing container in which the heating device is installed.
